(19) United States
(12) Patent Application Publication
(10) Pub. No.: US 2003/0114202 A1
(43) Pub. Date: Jun. 19, 2003

(54) Hands-free telephone system for a vehicle

(76) Inventors: Jung-Bum Suh, Yongin-city (KR); Ha-Yong Chung, Suwon-city (KR)

Correspondence Address: Pennie & Edmonds, LLP, 3300 Hillview Avenue, Palo Alto, CA, 94304, US

(21) Appl. No.: 10/315,775

(22) Filed: Dec. 10, 2002

(30) Foreign Application Priority Data
Dec. 18, 2001 (KR) 2001-0080547

(51) Int. Cl. H04B 1/06; H05K 11/02; H04M 1/00; H04B 1/38

(52) U.S. Cl. 455/569; 455/563; 455/566; 455/345

(57) ABSTRACT

The method and system of the invention increase the convenience of making a call on a portable phone and improve the safety of making the call while driving a vehicle. The system includes a communication module for wireless voice and character data transmission between the hands-free system and the portable phone and provides for voice command driven use of the portable phone without requiring a physical connection. The method provides for registering the entries on the portable phone into the system and for placing a call on the portable phone using the system.

### FIELD OF THE INVENTION

The present invention relates to a hands-free telephone system for a vehicle, and more particularly, to a hands-free telephone system for a vehicle that has improved convenience and is readily adaptable to a next generation communication environment.

### BACKGROUND OF THE INVENTION

A typical hands-free system is composed of a hands-free kit that is connectable to an earphone jack of the portable phone, the microphone, an amplifier, speaker, and a traffic switch, etc. In this conventional hands-free system, the driver must usually use keys on the portable phone to access functions, other than when answering a phone call or re-dialing a recently dialed phone number. In addition, every time they enter the vehicle the driver must connect the portable phone to the hands-free system, and attach a transmitter to the earphone jack even where wireless earphones are provided.

Entries are registered in a typical hands-free system according to a method where the system first checks to see whether the portable phone is connected to the system. The method then continues to determine whether hands-free system needs to be updated with entries, based on how many entries are in the system versus the number detected in the portable phone. These entries are updated by the hands-free system using voice commends to guide the user through a series of steps and responding to voice commands from the user that verify the entry and register it into the hands-free system. A registry entry management method for a portable phone and a hands-free kit, as described above, for registering names using voice recognition is disclosed in Korean Laid-open Patent Publication No. 1999-018665.

### SUMMARY OF THE INVENTION

The present invention makes it unnecessary to connect a portable phone to the hands-free system. A preferred embodiment of the hands-free system of the present invention enhances mobile communication using a portable phone, and includes: a memory for storing telephone numbers; a voice recognition module for receiving a name and recognizing it; a voice synthesizing module for outputting a name according to an instruction of the voice recognition module or according to character information displayed on said portable phone; a microprocessor for controlling the hands-free system based on signals received from the memory and the voice recognition module; an input/output (I/O) module for inputting or displaying a telephone number of the portable phone; and a communication module for enabling voice and character data transmission through wireless communication so as to enable making a phone call through verbal commands and outputting voice and character information through verbal commands according to an input of the voice and character information.

An additional preferred embodiment of a hands-free system for a portable phone according to the invention, comprises: a microprocessor with a computer program embedded therein; a communication module configured to detect the presence of at least one portable phone and to facilitate the wireless exchange of information between the microprocessor and the at least one portable phone; a voice recognition module configured to: receive a data packet representing a spoken word from the microprocessor; create a second data packet representing said spoken word using signals from a microphone; determine whether the first and second data packets match; and output the result of whether the first and second data packets match to the microprocessor; a memory for storing the data packets and the information; a voice synthesizing module configured to translate the data packets and the information into signals that upon conversion into sound are understood to be spoken words; an amplifier and speaker for converting said data packets and the information into sound; a keypad; a display; and an input/output module configured to: relay input from the keypad to the microprocessor; and relay output from the microprocessor to the display; wherein said hands-free system automatically recognizes the presence of at least one portable telephone, interfaces with the at least one portable telephone, and allows the operation of the at least one portable telephone through voice commands through the microphone and input from the keypad.

An additional preferred embodiment of a method for operating a hands-free system for a portable, comprises: having the hands-free system automatically recognize the presence of at least one portable phone; wirelessly interfacing the hands-free system with the at least one portable phone; transferring information from the at least one portable phone to the hands free system, wherein the hands-free system receives at least one data packet with a corresponding phone number from said at least one portable phone; constructing voice commands for the hands-free system that are specific for the at least one portable phone recognized, the constructing comprising: prompting a user to repeat a spoken name, wherein the spoken name was generated using a data packet; creating a second data packet representing the repeated spoken name using signals from a microphone; determining whether the first and second data packets match; and storing the first and second data packets as names if they match; and operating in response to commands input by the user to the hands-free system, said operating comprising: responding to voice commands from the user; and responding to commands input by the user through a keypad.

### BRIEF DESCRIPTION OF THE DRAWINGS

Preferred embodiments of the present invention will hereinafter be described in detail with reference to the accompanying drawings, in which:

FIG. 1 is a flow chart of a registry entry management method in a voice recognition module of a hands-free system;

FIG. 2 is a flow chart of a process for registering names in the memory of the hands-free system shown in FIG. 1;

FIG. 3 is a block diagram of a hands-free system of a vehicle according to a preferred embodiment of the present invention; and

FIG. 4 is a front view of a front panel of the hands-free system according to a preferred embodiment of the present invention.

Like numerals refer to similar elements throughout the several drawings.

### DETAILED DESCRIPTION OF THE PREFERRED EMBODIMENTS

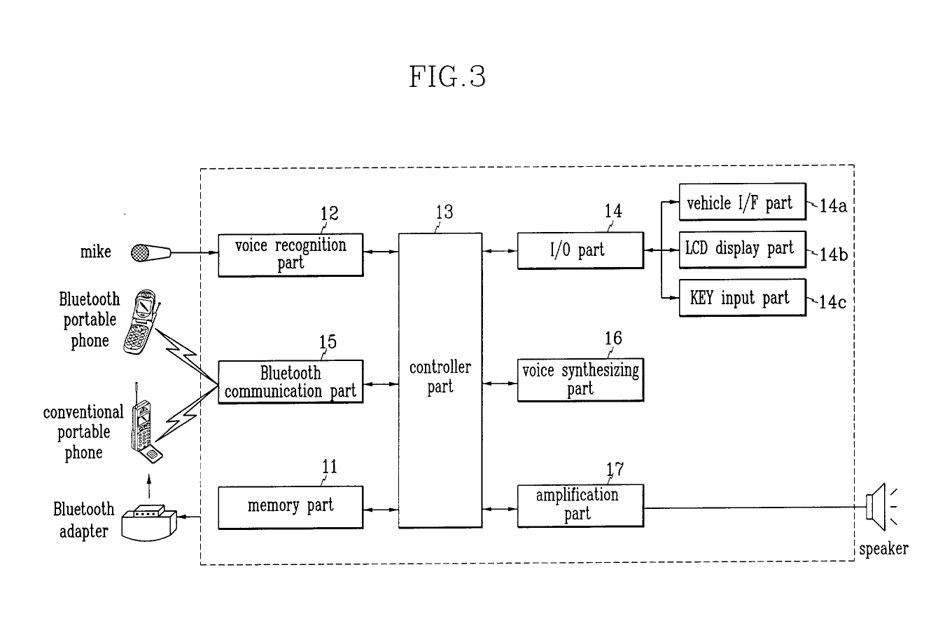

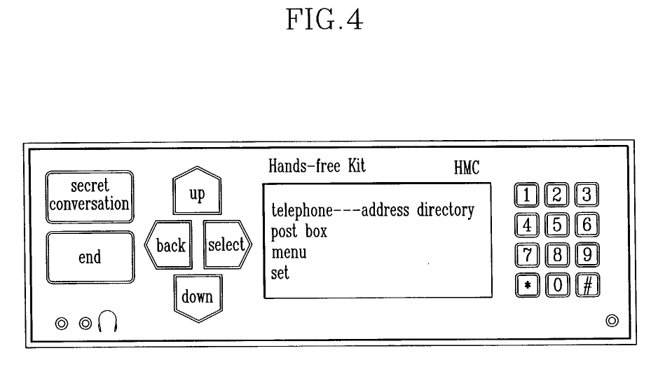

Referring to FIGS. 3 and 4, a hands-free system 10 according to a preferred embodiment of the present invention enhances communication using a portable phone in a vehicle. System 10 may comprise: a memory 11 for storing various telephone numbers and related information from the portable phone; a voice recognition module 12 for receiving a name (through a microphone, for example) and recognizing it, thereby facilitating placing a telephone call; a voice synthesizing module 16 for outputting a name according to an instruction from said voice recognition module 12, or according to an instruction from character information displayed on said portable phone; a microprocessor 13 for controlling said hands-free system based on signals received from said memory 11 and said voice recognition module 12; an I/O module 14 for inputting or displaying a telephone number of said portable phone; and a communication module 15 for enabling voice and character data transmission through wireless communication.

Communication module 15 enables making a phone call and outputting voice and character information using verbal commands. In a preferred embodiment, communication module 15 is a Bluetooth™ communication module, which is now well understood by persons of ordinary skill in the art. The specification for Bluetooth™ technology is developed, published and promoted by the Bluetooth™ Special Interest Group (Bluetooth™ SIG), Inc. Bluetooth™ technology is described in: Dee Baker, Diane Gilster, and Roy Gilster, Bluetooth™ End to End, John Wiley & Sons, Jan. 15, 2002; and Robert Morrow, Bluetooth™ Operation and Use, McGraw-Hill Professional, Jun. 14, 2002.

The I/O module 14 comprises: an interface (I/F) module 14a that enables the hands-free system to communicate with the vehicle; an LCD display module 14b for displaying telephone numbers; and a keypad or key input module 14c for inputting the telephone number of the portable phone to the memory 11. The keypad and display functions could be performed by one user interface. In another preferred embodiment of the invention, system 10 is modified for use, resulting in the elimination of I/F module 14a.

When the system is started, if two or more portable phones in the vicinity are detected by the Bluetooth™ communication modules, their telephone numbers are displayed on the LCD display module 14b of the I/O module. The voice synthesizing module 16 synthesizes the voice of the portable phone user, and is connected to an amplification module 17 that amplifies the voice and outputs it through a speaker. During the output of the voice, the vehicle's audio system is muted by commands transmitted through the vehicle I/F module 14a. The portable phone used with the hands-free system of the present invention should be a portable phone having a built-in Bluetooth™ module or a portable phone enabling Bluetooth™ communication by having a Bluetooth™ adapter attached to it.

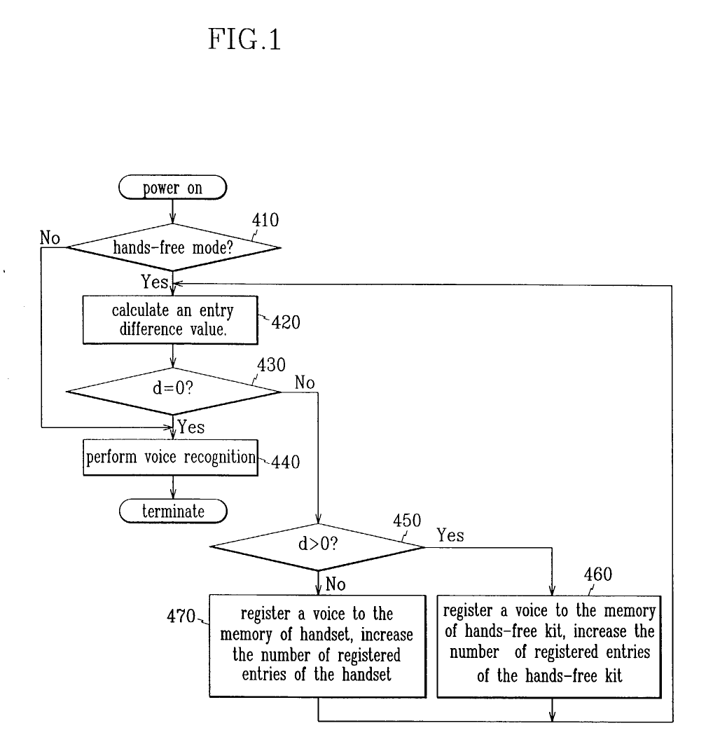

The system is used in the following manner. Referring to FIG. 1, in step 410, a microprocessor checks the hands-free kit connection part to verify that the jack of the hands-free kit and the portable phone are connected to each other and that the portable phone is mounted on the holder. If so, the microprocessor recognizes that they are in hands-free mode, and, in step 420, calculates an entry difference value by subtracting the number of registered entries in the hands-free kit from the number of registered entries of the portable phone.

In step 430, the microprocessor checks if the entry difference value is zero. If it is zero, in step 440 the microprocessor performs voice recognition. If it is not zero, in step 450 the microprocessor checks whether the entry difference value is larger than zero. If so, in step 450 the microprocessor registers a prerecorded name in the memory of the hands-free kit and increases the number of registered entries of the hands-free kit. But, if the entry difference value is not greater than zero, the microprocessor registers the prerecorded name to the memory of the portable phone and increases the number of registered entries in the portable phone in step 470.

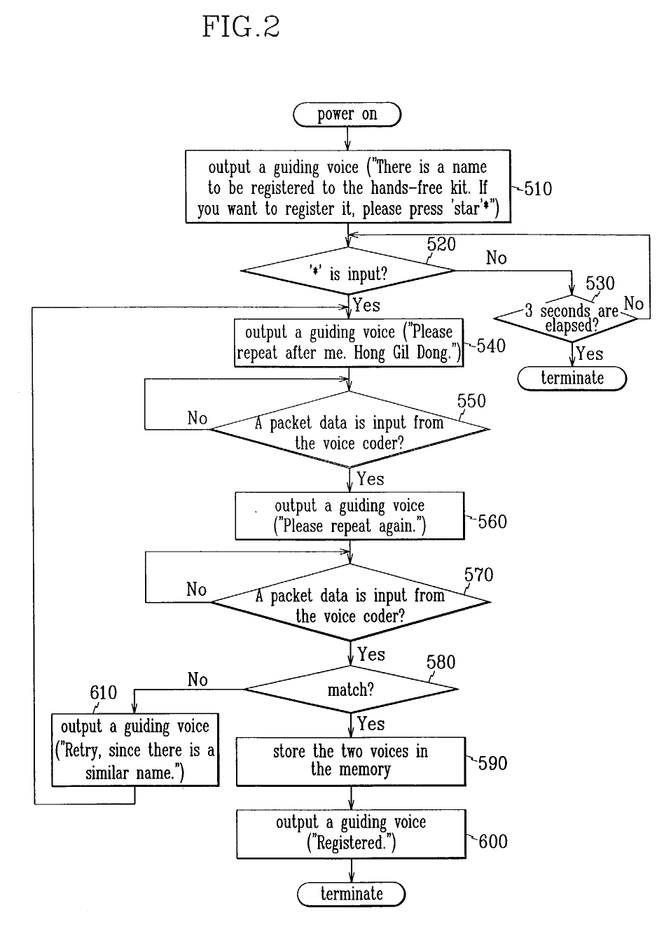

Referring to FIG. 2, this operation is performed at the time the portable phone is mounted in the hands-free holder to update the names in the hands-free kit with the names in the portable phone. First, in step 510, the microprocessor outputs a guiding voice that asks whether a driver wants to register a name to the hands-free kit. This guiding voice is output through a D/A converter and a speaker. In step 520, the microprocessor checks whether the key ‘*’ is input. If the input is not detected, the microprocessor proceeds to step 530 and checks whether a predetermined time (for example, three seconds) has elapsed. If so, the microprocessor concludes that the driver has no intention of registering and terminates the operation. If it has not elapsed, the microprocessor returns to step 520 to again check whether the key ‘*’ is input. When the key ‘*’ input is detected, step 540 begins the process of having the driver register names that have already been registered in the portable phone, but have never been registered in the hands-free kit. In step 540, a guiding voice requesting a repetition of the relevant name is output (e.g., “Please repeat after me. [Name]”). Here, the phrase “Please repeat after me” is output using a guiding message recorded in advance in memory, and the name is output by reading a first data packet from a set stored in a voice reproduction data region of the portable phone memory.

If the driver inputs the name through a microphone in response thereto, the name is transmitted to a voice coder in the form of a PCM (pulse code modulation) signal through an A/D converter. In general, a voice coder is an apparatus for converting analog voice signals into digital signals. The voice coder codes the PCM signal to generate a second data packet. Then, in step 550, the microprocessor checks whether this second data packet is input from the voice coder.

In step 560, the microprocessor outputs a guiding voice requesting a repetition (e.g., “Please repeat again.”). Then the microprocessor checks whether a third data packet from the voice coder is input, i.e., the voice of the driver responding to the second request of repetition. If the input is detected, in step 580, the microprocessor requests that a voice recognition module compare the two names and determines whether they match, and reports a result. The match is determined when a characteristic data index for each of the two names and a difference value (the difference in characteristic data between the two names) are transmitted from the voice recognition module to the microprocessor. If the microprocessor determines that the difference value is smaller than a predetermined threshold it considers the two names to match. Then, in step 590, the microprocessor requests that the voice recognition module store the two names in memory. In general, a voice recognition module is an apparatus programmed to convert analog voice signals into digital signals and to extract information from the digital voice signals.

After registering the two matching names, in step 600 the microprocessor outputs a guiding voice notifying the user that the registration is complete (e.g., “Registered”). But, if the two names did not match in step 580, in step 610 the microprocessor outputs a guiding voice requesting a retry (e.g., “Retry, since the names do not match.”) and returns to step 540.

The operation of the hands-free system according to the embodiment of the present invention described above is as follows. Referring again to FIG. 3, a hands-free system enables the driver to make a phone call freely and eliminate danger. The hands-free system 10 frees the eyes and hands of the driver during phone communication by providing a plurality of functions, such as: wireless connection of the portable phone to the hands-free system, based on the Bluetooth™ protocol that enables voice and character data transmission; voice activation for placing calls; and voice synthesis enabling voice recognition and conversion of displayed information into announced or “spoken” information.

The hands-free system automatically detects portable phones when the driver gets into the vehicle carrying the portable phone, if the phone is Bluetooth™ equipped. This is called “automatic detection.” If two or more portable phones are detected the system displays the telephone numbers on the LCD display module 14b and makes the driver select the telephone number of the appropriate portable phone using voice commands. If only one portable phone is detected, it is automatically selected. Then, information from the telephone directory and menu stored in the selected portable phone is automatically transmitted to the hands-free system.

The driver states “answer the call,” to answer a phone call. In response, the hands-free system mutes the vehicle audio system. The call is terminated when the driver says “end.” At this time the audio system is released from the mute state. When the driver wishes to place a call, and says “phone call”, the hands-free system switches to a mode of making a phone call and mutes the audio system. If the driver verbally states a number, or a name that is in the portable phone telephone directory, then the hands-free system informs the driver of what it recognizes by means of the voice synthesizing module. If the driver verbally confirms a desired telephone number or name and says “make the call”, then the hands-free system connects to the appropriate telephone number and informs the driver of the fact that the portable phone of the appropriate phone number is on standby for reception. When the driver says “end” upon completion of the conversation, the call is terminated and the audio system is released from the mute state.

When the driver says “character message,” then the hands-free system mutes the audio system and reads by means of the voice synthesis a character message currently stored in the portable phone. In this embodiment, the character message was acquired through the Short Message Service (SMS) that allows short character messages to be communicated to a portable telephone.

It is also possible for the driver, or for another vehicle occupant, to access the functions described above by using the input key pad on the front panel of the hands-free system, as shown in FIG. 4.

The present invention as described above makes possible: automatic wireless connection; automatic transmission of the telephone number of the portable phone; and mobile communication, regardless of whether the portable phone is in a pocket or a bag, so long as it is in the vicinity of the system. In the case of the portable phone having the built-in Bluetooth™ module, compatibility is guaranteed, since it has a standardized connection method. In the case of the conventional portable phone, compatibility is guaranteed by using the Bluetooth™ adapter. Thus, the entire operation of the portable phone can be performed using voice commands. The name and telephone number can be chosen by voice command. The character display information can be guided by voice commands. And character messages can be converted into voice messages.

The present invention is a technology that uses voice recognition, voice synthesis, and wireless communication. In a preferred embodiment of the invention, the wireless communication uses Bluetooth™ technology. Each Bluetooth™ module must get authorization from the Bluetooth™ SIG (Special Interest Group), an international authorization institute. If a Bluetooth™ module is authorized, it is assigned its own ID. Each Bluetooth™ module has an ID that is unique in the world. Compatibility and security are guaranteed for communication between the authorized modules. If the hands-free system user properly uses the functions as described above, 100% compatibility with Bluetooth™ equipped portable phones is possible and the driver does not need to separately register the telephone numbers in the portable phone with the hands-free system.

Using Bluetooth™, once the portable phone and the hands-free system are connected, information, such as the telephone directory, menu, and battery condition is automatically transmitted to the hands-free system from the portable phone. The hands-free system has a memory for the telephone directory, always downloading the most recent information from the portable phone it is connected to. Therefore, if the telephone directory in the portable phone is updated, the updated telephone directory is automatically sent to the hands-free system and the driver does not have to worry about confusion due to a difference in data between the portable phone and the hands-free system. Thus, without having to mount the portable phone in any holder, information automatically transmitted to the hands-free system from the portable phone, allowing the user to monitor the condition of the portable phone, make phone calls by voice commands (provided the name exists in the telephone directory), and remotely control the menu of the portable phone by voice commands.

In addition, with the hands-free system for a vehicle according to the embodiment of the present invention, it is possible to control all the functions of an Audio (or Automatic) Response System (“ARS”) telephone using voice commands. That is, if the driver verbally states a number, in the conversation condition, the voice recognition module 12 recognizes the number and instructs the voice synthesizing module 16 to reproduce a key tone corresponding to the recognized number (each number button of a telephone has a tone of a specific frequency corresponding thereto). It is also possible to hear a voice message sent to the ARS phone through the hands-free system.

The hands-free system for a vehicle according to the preferred embodiments of the present invention receives information from a portable phone via the Bluetooth™ module and delivers the information using voice synthesis or a combination of displayed characters on LCD display module 14b and voice synthesis. Thus, the driver has all the information that he requires for the operation of the hands-free system.

The present invention increases driver safety and is convenient, since a portable phone can be operated through the system without being manually connected to the system. The hands-free system can also be adapted to the next generation automobile communication environment in which other vehicle systems will be equipped with Bluetooth™ modules. Furthermore, connection to multiple portable phones is possible, allowing any passenger in a vehicle to use the system, or to hear conversation. In addition, when the portable phone for IMT-2000 is standardized, the driver will be able to retrieve various other kinds of information through the hands-free kit.

While this invention has been described with reference to the preferred embodiments, it is to be understood that the invention is not limited to the disclosed embodiments, but covers various modifications and equivalent arrangements included within the spirit and scope of the appended claims.

What is claimed is:

1. A hands-free system for a portable phone, the system comprising:
a voice recognition module for receiving a name and recognizing it;
a memory for storing at least one telephone number and at least one name;
a voice synthesizing module, wherein said voice synthesizing module outputs a name according to an instruction of said voice recognition module;
a microprocessor for controlling said hands-free system based on signals received from said memory and said voice recognition module;
an I/O module for inputting or displaying a telephone number of said portable phone; and
a communication module for transmitting voice and character data through wireless communication, wherein said hands-free system allows a user to place a phone call using voice commands, and said hands-free system outputs information through said voice synthesizing module based on input name, telephone number, and character information.

2. The hands-free system of claim 1, wherein said I/O module comprises:
an interface module communicates with a vehicle;
an LCD display module for displaying said telephone number of said portable phone; and
a key input module for inputting said telephone number of said portable phone to said memory.

3. The hands-free system of claim 1, wherein said system detects portable phones and displays telephone numbers of said detected portable phones on said I/O module.

4. The hands-free system of claim 1, further comprising an amplification module connected to the voice synthesizing module to amplify the voice and output it through a speaker.

5. The hands-free system of claim 1, wherein said portable phone comprises a built-in module for communicating with said communication module.

6. The hands-free system of claim 1, wherein said portable phone is equipped with an adapter for communicating with said communication module.

7. The hands-free system of claim 1, wherein during the output of the voice, an audio system of a vehicle is muted.

8. The hands-free system of claim 1, wherein said voice synthesizing module outputs a voice according to character information displayed on said portable phone.

9. A hands-free system for a portable phone, comprising:
a microprocessor programmed to provide voice command driven use of the portable phone;
a communication module configured to detect the presence of at least one portable phone and to facilitate the wireless exchange of information between the microprocessor and the at least one portable phone;
a voice recognition module configured to:
receive a data packet representing a spoken word from the microprocessor;
create a second data packet representing said spoken word using signals from a microphone;
determine whether the first and second data packets match; and
output the result of whether the first and second data packets match to the microprocessor;
a memory for storing the data packets and the information;
a voice synthesizing module configured to translate the data packets and the information into signals that upon conversion into sound are understood to be spoken words;
an amplifier and speaker for converting said data packets and the information into sound;
a user interface; and
an input/output module configured to:
relay input from the user interface to the microprocessor; and
relay output from the microprocessor to the user interface;
wherein said hands-free system automatically recognizes the presence of at least one portable telephone, interfaces with the at least one portable telephone, and allows the operation of the at least one portable telephone through voice commands through the microphone and input from the user interface.

10. The hands-free system for a portable phone of claim 9, further comprising a vehicle interface, and wherein said input/output module is further configured to relay commands from the microprocessor to the vehicle through the vehicle interface.

11. A method for operating a hands-free system to allow a user make a call using a portable phone, comprising:
having the hands-free system automatically recognize the presence of at least one portable phone;
wirelessly interfacing the hands-free system with the at least one portable phone;
transferring information from the at least one portable phone to the hands free system, wherein the hands-free system receives at least one data packet with a corresponding phone number from said at least one portable phone;
constructing voice commands for the hands-free system that are specific for the at least one portable phone recognized, the constructing comprising:
prompting a user to repeat a spoken name, wherein the spoken name was generated using a data packet;
creating a second data packet representing the repeated spoken name using signals from a microphone;
determining whether the first and second data packets match; and
storing the first and second data packets as names if they match; and
operating in response to commands input by the user to the hands-free system, said operating comprising:
responding to voice commands from the user; and
responding to commands input by the user through a keypad.

12. The method of claim 11, further comprising relaying commands from the hands-free system to the vehicle through a vehicle interface.
